(19) United States
(12) Patent Application Publication
(10) Pub. No.: US 2018/0040752 A1
(43) Pub. Date: Feb. 8, 2018

(54) PHOTOVOLTAIC SYSTEMS FOR COLLECTION OF DIFFUSE AND DIRECT SUN LIGHT AND SYSTEMS AND METHODS OF OPTIMIZING SAME

(71) Applicant: Lumen LLC, Seattle, WA (US)

(72) Inventor: Beate Liepert, Seattle, WA (US)

(21) Appl. No.: 15/623,860

(22) Filed: Jun. 15, 2017

Related U.S. Application Data
(60) Provisional application No. 62/350,994, filed on Jun. 16, 2016.

(51) Int. Cl. H01L 31/0445; H01L 31/02; H01L 31/0475

(52) U.S. Cl. CPC H01L 31/0445; H01L 31/0475; H01L 31/02008

(57) ABSTRACT

The invention described herein are photovoltaic systems which are optimized to capture direct diffused sunlight.

### CROSS-REFERENCES TO RELATED APPLICATIONS

This application takes priority to U.S. Provisional Application 62350994, filed on Jun. 16, 2016, and is incorporated herein by reference.

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### BRIEF DESCRIPTION OF INVENTION

Photovoltaic (“PV”) systems, known in the art, of various scales (e.g. distributed roof mounted systems to utility-scale installations), are optimized for collecting direct sunlight or direct irradiance. In the western part of the United States, clear-sky, direct irradiance on a horizontal surface is approximately 7 times stronger than diffuse sunlight on a horizontal surface; in the eastern part of the United States, clear-sky, direct irradiance is approximately 5 times stronger than diffuse irradiance on a horizontal surface. Consequently, most photovoltaic systems, known in the art, are designed to collect direct irradiance with flat panels that are perpendicular to the incoming direct sunlight (this irradiance is called direct normal irradiance/sunlight). However, these panels do not efficiently collect sunlight when there are clouds.

In many, if not most regions of the world, cloud-free days are rare. On the average, 60% of the Earth is covered in clouds at any given moment. In some cases, environments may simply have more overcast days than cloud-free days. In other case, even though a day may be cloud-free, direct sunlight may be blocked by pollution. In the United States, for example, the skies are, on average, cloud free only 25% of all daytime hours.

Furthermore, areas of the world that are mostly cloud-free are, more often than not, remote and far distances from regions of high electricity demand. It is well known, that carrying energy over a distance for use is not efficient and has cost of its own. As an example, consider the desert environments of the United States that are the most efficient place to gather solar energy however, those areas are most often not urban centers. In urban centers space for solar panels is also limited. FIG. 1 illustrates the differences between total incoming sunlight on a horizontal area and direct normal solar irradiance distribution in United States.

In addition to its poor spatial distribution, direct normal irradiance has the added disadvantage of high temporal variability in most U.S. regions. FIG. 1 shows differences between global horizontal and direct normal solar irradiance distribution in United States. FIG. 2 shows typical diurnal cycles of diffuse and total (direct plus diffuse) solar irradiance for a summer day in Seattle, Wash. The graph illustrates that diffuse irradiance (also called ambient light) is much less intermittent and is always present during daytime hours even when it is cloudy. Diffuse light is hence a more reliable, albeit less intense, source of energy compared to direct normal irradiance. The extreme cloudiness of the Pacific Northwest makes it a region that would benefit greatly from improved use of diffuse irradiance for solar energy production. Collecting significant quantities of diffuse light with flat panels, however, requires large areas that are often not available in urban or suburban centers.

There is a need to effectively utilize diffuses sun light in order utilize this natural resource and spatially expand the feasibility of solar energy by optimizing the design of PV structures.

### DESCRIPTION OF THE SEVERAL VIEWS OF THE DRAWINGS

Other features and advantages of the present invention will become apparent in the following detailed descriptions of the preferred embodiment with reference to the accompanying drawings, of which:

FIG. 1 shows differences between global horizontal and direct normal solar irradiance distribution in United States;

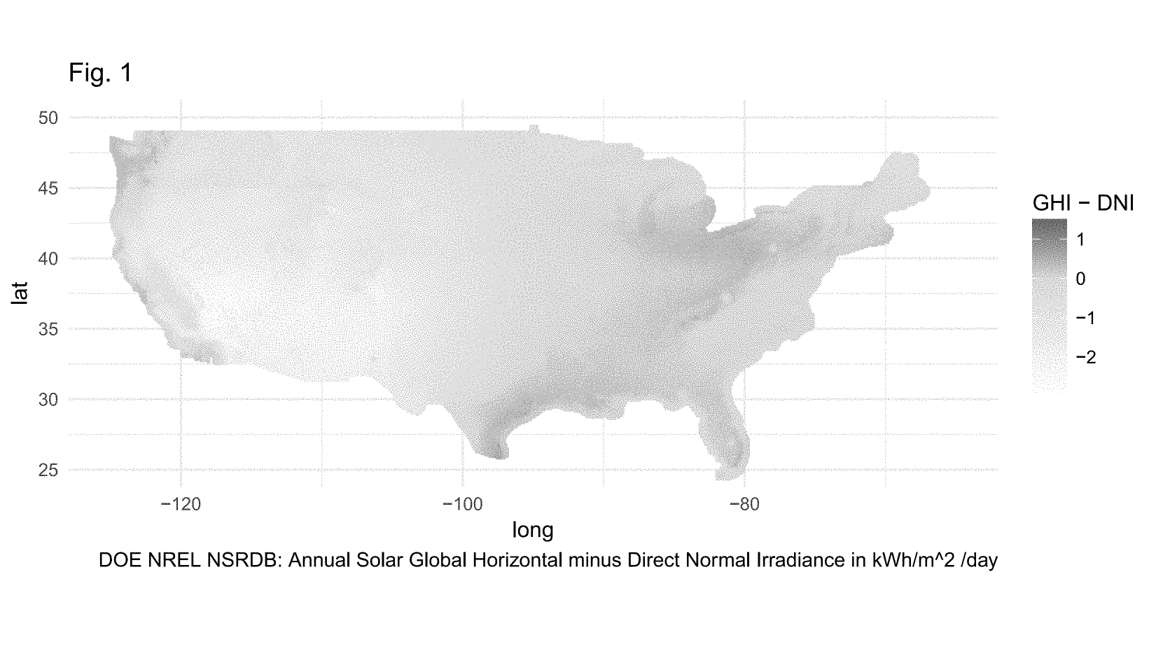

FIG. 2 shows typical diurnal cycles of diffuse and total (direct plus diffuse) solar irradiance for a summer day in Seattle, Wash.

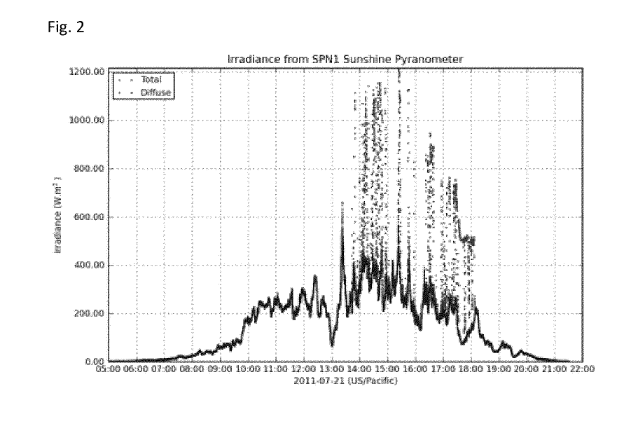

FIG. 3 is an embodiment of a PV system;

FIG. 4 is an embodiment of a PV system;

FIG. 5 is an embodiment of a PV system;

FIG. 6 is an embodiment of a PV system;

FIG. 7 is an embodiment of a PV system;

FIG. 8 is an embodiment of a PV system;

FIG. 9 is an embodiment of a PV system.

### DETAILED DESCRIPTION OF THE INVENTION

In the following detailed description, reference is made to the accompanying drawings, which form a part hereof. In the drawings, the use of similar or the same symbols in different drawings typically indicates similar or identical items, unless context dictates otherwise.

The illustrative embodiments described in the detailed description, drawings, and claims are not meant to be limiting. Other embodiments may be utilized, and other changes may be made, without departing from the spirit or scope of the subject matter presented here.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

The present application uses formal outline headings for clarity of presentation. However, it is to be understood that the outline headings are for presentation purposes, and that different types of subject matter may be discussed throughout the application (e.g., device(s)/structure(s) may be described under process(es)/operations heading(s) and/or process(es)/operations may be discussed under structure(s)/process(es) headings; and/or descriptions of single topics may span two or more topic headings). Hence, the use of the formal outline headings is not intended to be in any way limiting. Given by way of overview, illustrative embodiments include optimized photovoltaic systems and structures for collecting diffused and direct sun light. A photovoltaic system is comprised of at last one photovoltaic structure which may include at least one photovoltaic cell.

In some embodiments, new shapes for PV structures based on vegetation architecture is disclosed. Vegetation has adapted to ambient light environments through millions of years of evolutionary pressure. Vegetation models of various complexities that calculate the amount of sunlight available for photosynthesis on the leaf/blade/needle level are used in many applications in ecosystem, atmospheric science, climate, and remote sensing research.

An important term in ecosystem studies is leaf area index (LAI), which describes the ratio of area of leaves to the area of the ground beneath them. The corresponding ratio for PV structures is the area of a PV cell to area of ground or cell area index (CAI). This parameter quantifies material use and space requirements, which are crucial information for space-limited and distributed solar systems in dense urban settings.

Typical natural LAIs range from approximately 1 for grasses, 2 for boreal conifers, and 5 for temperate deciduous trees. According to one embodiment, a 3-dimensional numerical tree model may be used to design PV systems. PV systems can also be described as topography. In some embodiments, the 3D field (X, Y, Z) may be subdivided into volume elements (so-called voxels) (xᵢ, yⱼ, Zₙ). The radiative transfer through the voxels are calculated. All models are calculated in a scale without units. In some embodiments, structures are z-axis-symmetric because an isotropic diffuse light field is be assumed.

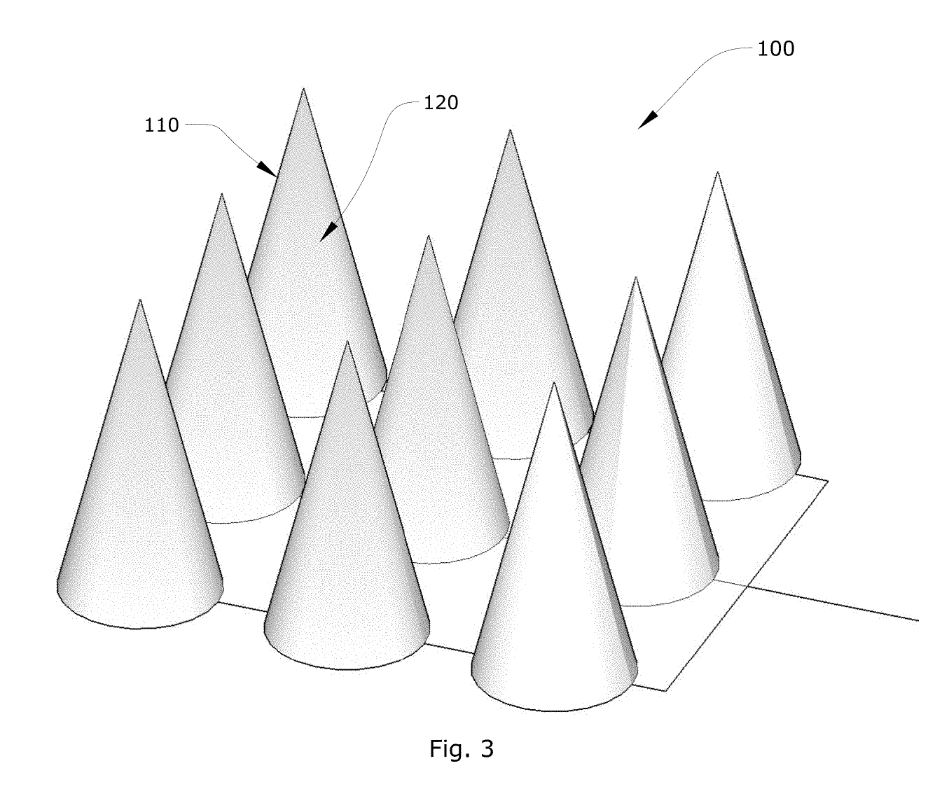

Referring to FIGS. 3,4,5, 6, according to an embodiment, a PV system (100, 200, 300, 400) is comprised of a PV structure (110, 210, 310). According to an embodiment, a PV system (100, 200, 300, 400) is comprised of at least one solar cell (120, 220, 320). In an embodiment, the PV system (100, 200, 300) is comprised of two or more solar cells (120, 220, 320) which may be operably attached to another solar cell or a PV system. In an embodiment, the solar cell (120, 220, 320) is thin film, constructed from material that includes light sensitive dye, or any other material that can collect solar irradiance by a method usable in a PV system. According to one embodiment, solar cell (120,220, 320, 420) may cover the entire surface area of a PV structure (110, 210, 310). According to one embodiment, any supporting structures required (e.g. converters) by the PV (110, 210, 310) structure may fit inside each PV structure (110, 210, 310).

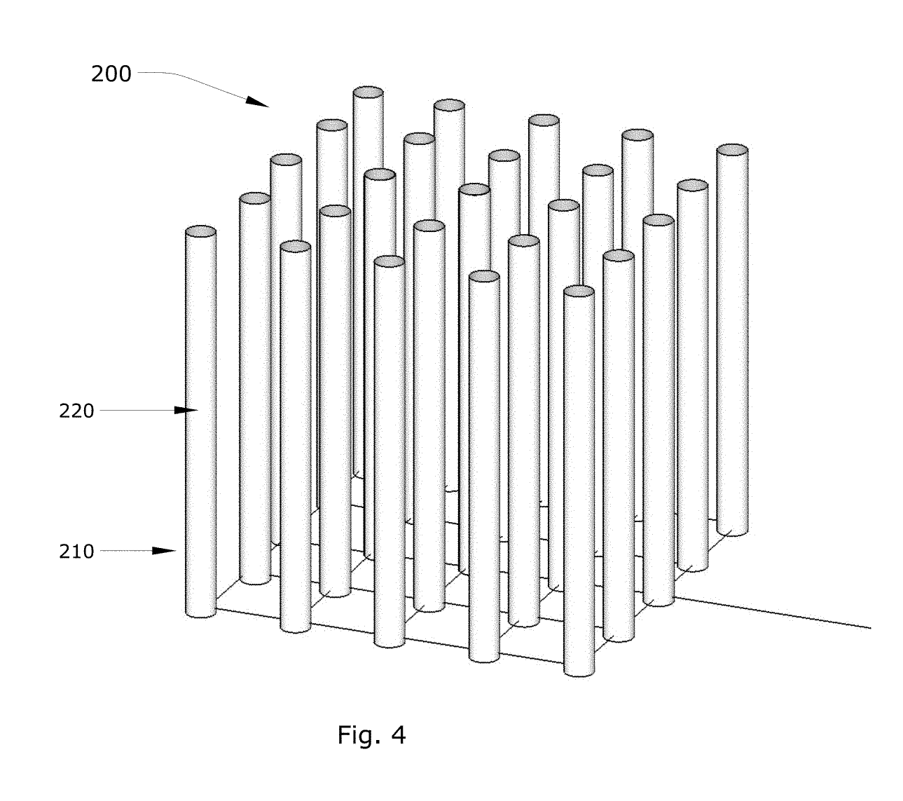

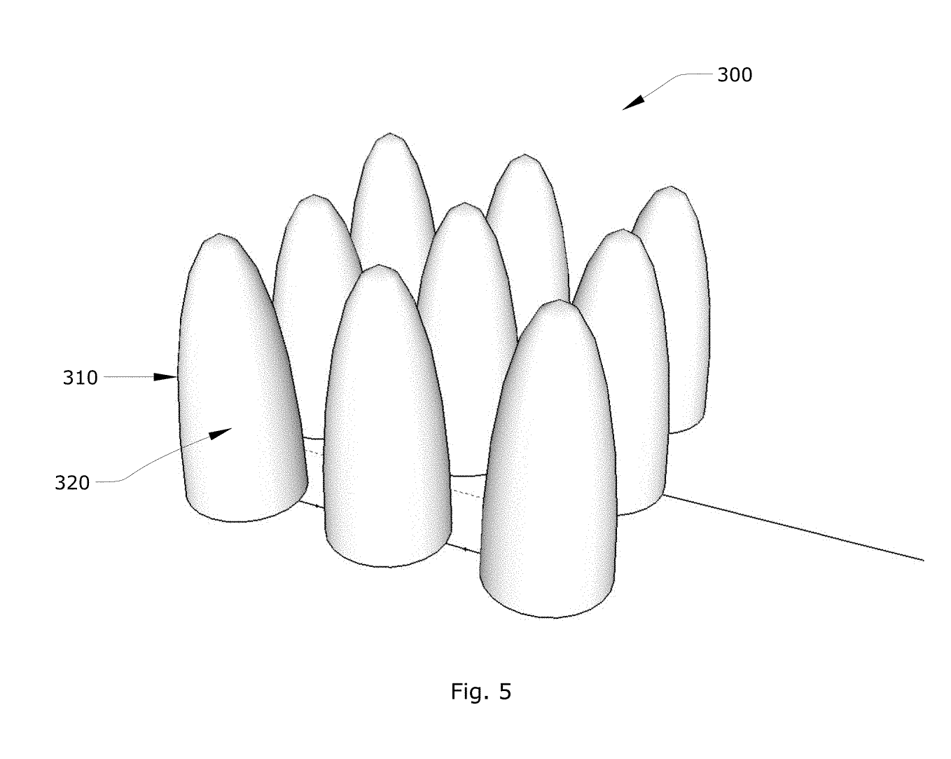

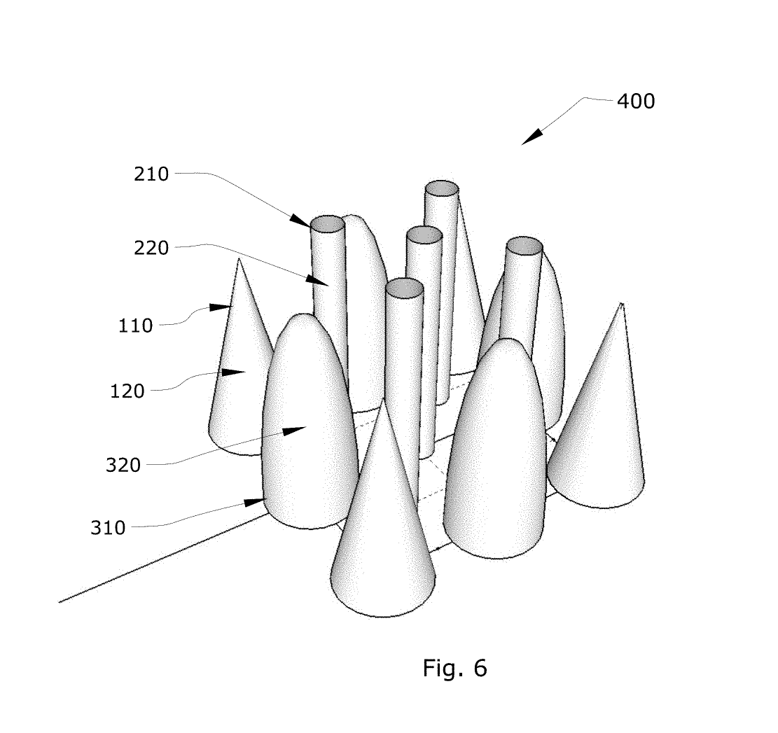

Referring to FIG. 3, according to an embodiment, a PV structure (110) may be shaped as a cone. According to an embodiment, a PV system (100) may be comprised of two or more cones. Referring to FIG. 4, according to an embodiment, a PV structure (210) may be shaped as a cylinder. According to an embodiment, a PV system (200) may be comprised of two or more cylinders. Referring to FIG. 5, according to an embodiment, a PV structure (310) may be shaped as a sphere or elongated sphere. According to an embodiment, the PV system may be comprised of two or more spheres or elongated spheres. Referring to FIG. 6, a PV system (400) may be comprised of at least one cone (110), cylinder (220), sphere or elongated sphere (320), or a combination thereof.

Referring to FIGS. 3, 4, 5, 6, in some embodiments that have two or more PV structures (110, 210, 310), the PV structures (110, 210, 310) may be placed equal distances apart. In some embodiments that have two or more PV structures (110, 210, 310), each PV structures (110,210, 310) may be equivalent in height. According to some embodiment, PV structures (110, 210, 310) may be optimized for height, width, and distance when a PV system (100, 200, 300) is comprised of two or more PV structures (110, 210, 310). In some embodiments, the axis of orientation of the PV structures (110, 210, 310) may be vertical. In some embodiments, the axis of the PV structures (110, 210, 310) may be tilted. According to another embodiment, orientation optimization around the z-axis may be determined.

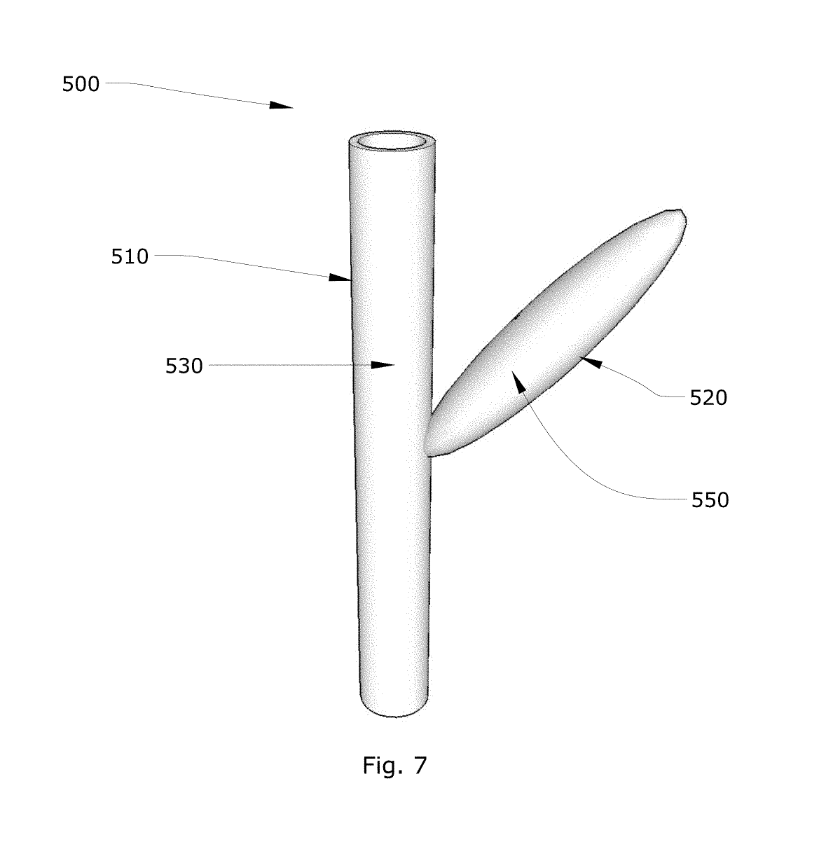

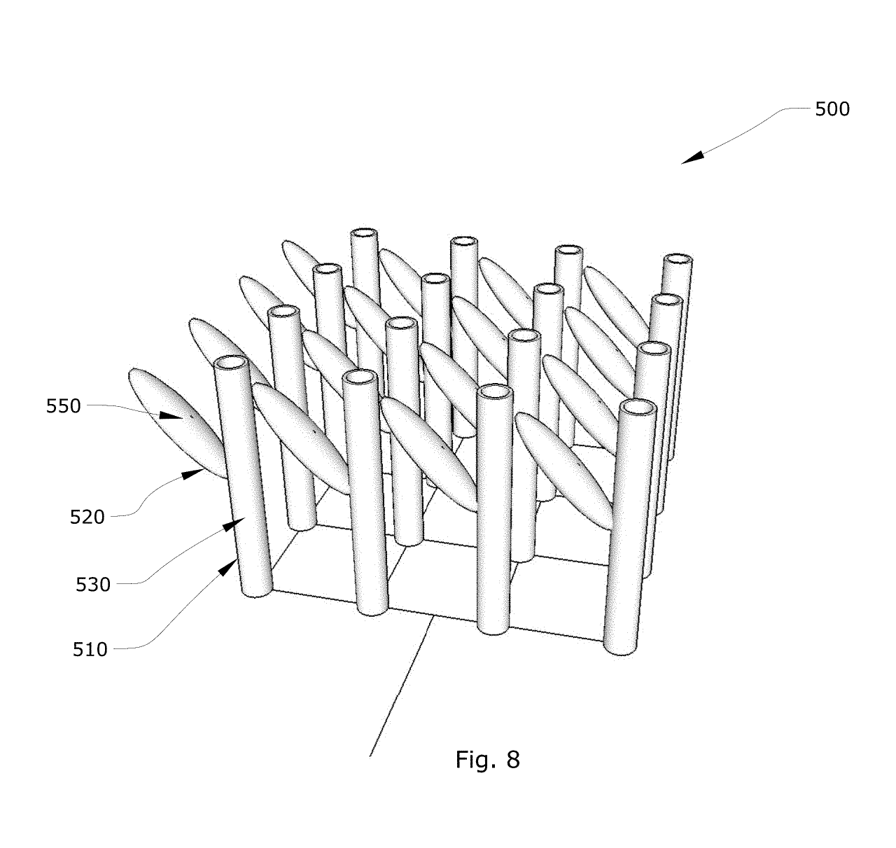

Referring to FIGS. 7 and 8, according to an embodiment, a PV system (500) may be comprised of at least one PV structure (510) where the PV structure is a base. According to an embodiment, more than one base (510) may be operably stacked to scale a PV system (500).

According to an embodiment, the PV structure (510) is further comprised of an appendage (520). According to an embodiment, the appendage (520) is removably and operably attached to the base (510). According to an embodiment, more than one appendage (510) may be removably and operably attached to at least one base (510) to scale the PV system (500).

According to one embodiment, the base (510) may be comprised of at least one solar cell (530). In an embodiment, the base (510) is comprised of two or more solar cells (530) which are operably attached to the base (510). In an embodiment, the solar cell (530) is thin film, constructed from material that includes light sensitive dye, or any other material that can collect solar irradiance in a method usable in a PV system (500).

According to one embodiment, the appendage (520), may be comprised of at least one solar cell (550). In an embodiment, the appendage (520) is comprised of two or more solar cells (550) which are operably attached to the appendage. In an embodiment, the solar cell (550) is thin film, constructed from material that includes light sensitive dye, or any other material that can collect solar irradiance in a method usable in a PV system (500). According to one embodiment, the structure, number, and/or shape of the base (510) and the appendage (520) are optimized to capture maximum solar irradiance in a particular location.

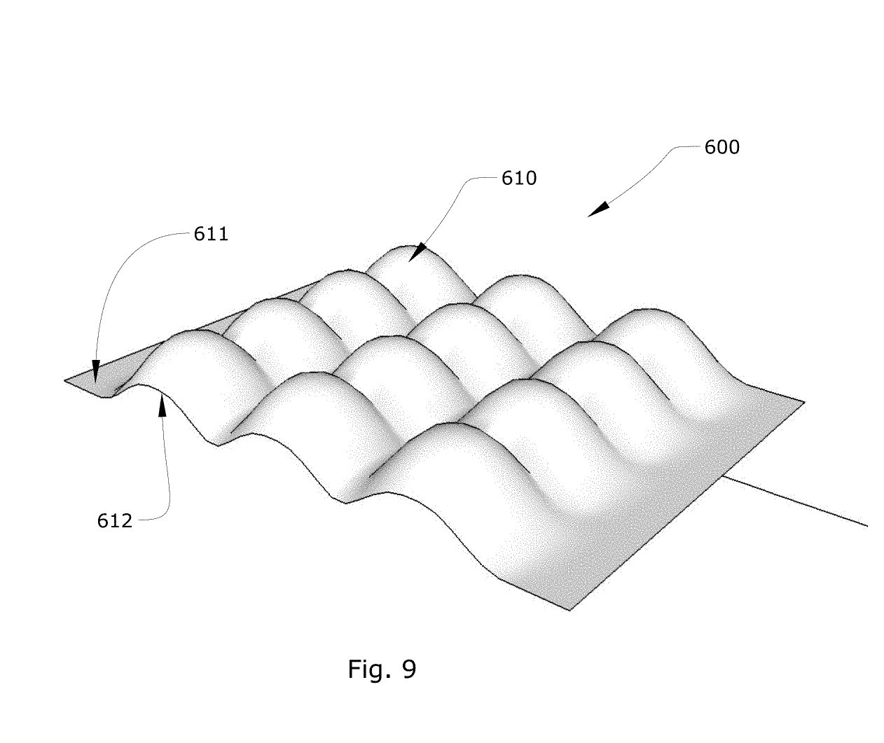

Referring to FIG. 9, according to an embodiment a photovoltaic system (600) for collecting diffused and direct sunlight is comprised of at least one solar cell (610) having a surface that is substantially conformant with a plane (611), and comprising at least one raised portion relative to the plane (612). According to an embodiment, the photovoltaic system (600) has more than one solar cell (610), where each solar cell operably mates with another solar cell (610). According to an embodiment, the photovoltaic system (600) is thin film, constructed from material that includes light sensitive dye, or any other material that can collect solar irradiance in a method usable in a PV system (600). According to one embodiment, number, shape and size of raised portion(s) (612) is optimized to capture maximum solar irradiance at a location.

It is claimed:

1. A scalable photovoltaic system for collecting diffused and direct light comprised of at least one solar cell having at least one concave, at least convex surface, or a combination thereof.

2. The photovoltaic system of claim 1 where the solar cell may be a sphere, elongated sphere, cylinder, or cone.

3. The photovoltaic system of claim 2 having two or more solar cells where the solar cells.

4. The photovoltaic system of claim 1 having two or more solar cells, where each solar cell is operably connected to at least one concave surface, at least one convex surface, or a combination thereof.

5. The photovoltaic system of claim 1, where the at least one solar cell is a thin film solar cell or constructed from material that includes light sensitive dye, or a combination thereof.

6. A portable, scalable photovoltaic system for collecting diffused and direct light comprising at least one base member and at least one appendage removably attached to the base; where the base is comprised of at least one solar cell, or the appendage is comprised of at least one solar cell, or the base is comprised of one solar cell and appendage is comprise of at least one solar cell.

7. The portable, scalable photovoltaic system of claim 6 having two or more bases; where the bases are removably attached to scale the photovoltaic system.

8. The photovoltaic system of claim 6 where the at least one solar cell is a thin film solar cell or constructed from material that includes light sensitive dye, or a combination thereof.

9. The photovoltaic system of claim 6 where the base member is tubular.

10. The photovoltaic system of claim 8 where the base member is comprised of two or more solar cells, where each solar cell is operably connected to at least one other solar cell to form the base member.

11. The photovoltaic cell of claim 6 where the appendage is comprised of two or more solar cells, where each solar cell is operably connected to form the appendage.

12. A photovoltaic system for collecting diffused light comprised of at least one solar cell having a surface that is substantially conformant with a plane, and comprising at least one raised portion relative to the plane.

13. The photovoltaic system of claim 12 having more than one solar cell, where each solar cell operably mates with another solar cell.

14. The photovoltaic system of claim 12 where the solar cell is a thin film solar cell or constructed from material that includes light sensitive dye, or a combination thereof.
